(19) United States
(12) Patent Application Publication
(10) Pub. No.: US 2012/0134014 A1
(43) Pub. Date: May 31, 2012

(54) LIGHT GENERATING DEVICE

(75) Inventors: Jong Sool Jeong, Deajeon (KR); Byung-seok Choi, Deajeon (KR); O-Kyun Kwon, Deajeon (KR)

(73) Assignee: ELECTRONICS AND TELECOMMUNICATIONS RESEARCH INSTITUTE, Daejeon (KR)

(21) Appl. No.: 13/281,463

(22) Filed: Oct. 26, 2011

(30) Foreign Application Priority Data
Nov. 26, 2010 (KR) 10-2010-0119030

(51) Int. Cl. H01S 5/20

(52) U.S. Cl. 359/344

(57) ABSTRACT

Disclosed is a light generating device which comprises a first reflective semiconductor optical amplifier emitting a first light along a first direction, a second reflective semiconductor optical amplifier emitting the second light in a direction opposite to the first direction, an optical distributer reflecting a part of an incident light and to pass the remaining of the incident light, and an optical comb filter passing a wavelength component of a specific period.

### CROSS-REFERENCE TO RELATED APPLICATIONS

This application claims the benefits, under 35 U.S.C §119, of Korean Patent Application No. 10-2010-0119030 filed Nov. 26, 2010, the entirety of which is incorporated by reference herein.

### BACKGROUND

Exemplary embodiments relate to an optical device, and more particularly, relate to a light generating device.

Optical communications have been researched as a mass communication technology. The optical communications may be made according to procedures including converting a transmission signal into a light at a transmitter side, transmitting the converted signal as a light via a medium such as an optical cable, and converting an input optical signal into an original signal at a receiver side. A representative optical communications technology may be a Wavelength Division Multiplexing Passive Optical Network (WDM-PON). The WDM-PON may make communications using a plurality of lights having different wavelengths.

Research on light generating devices generating a light having a periodic wavelength component may be made to establish the WDM-PON. Light generating devices generating a light having a periodic wavelength component may include light generating devices having a spectrum slicing manner and an external light source injection manner.

A light generating device of the spectrum slicing manner may use a manner of slicing amplified spontaneous emission (ASE) generated from an Erbium Doped Fiber Amplifier (EDFA) or a light generated from an incoherent broadband light source (BLS) such as a light emitting diode.

A light generating device of the external light source injection manner may use a manner of making spectrum slicing on a light generated from an external incoherent broadband light source and injecting the spectrum sliced light into a Fabry-Perot Laser Diode (FPLD).

### SUMMARY

A light generating device is provided to improve the reliability.

One aspect of embodiments of the inventive concept is directed to provide a light generating device which comprises a first reflective semiconductor optical amplifier configured to emit a first light along a first direction; a second reflective semiconductor optical amplifier being opposite to the first reflective semiconductor optical amplifier and configured to emit the second light in a direction opposite to the first direction; an optical distributer formed between the first and second reflective semiconductor optical amplifiers and configured to reflect a part of an incident light and to pass the remaining of the incident light; and an optical comb filter formed between the optical distributer and the first reflective semiconductor optical amplifier and configured to penetrate a wavelength component of a specific period.

In this embodiment, the optical distributer reflects a part of the second light and passes the remaining of the second light toward the optical comb filter.

In this embodiment, the optical distributer reflects a part of the first light in a direction opposite to the second direction and passes the remaining of the second light toward the second reflective semiconductor optical amplifier.

In this embodiment, the light generating device further comprises a third lens configured to focus a light reflected along the second direction from the optical distributer and to transfer the focused light to a first output port; and a fourth lens configured to focus a light reflected along a direction opposite to the second direction from the optical distributer and to transfer the focused light to a second output port.

In this embodiment, the light generating device further comprises a monitor photo diode configured to monitor a light reflected along a direction opposite to the second direction from the optical distributer.

In this embodiment, the light generating device further comprises a fifth lens configured to focus a light reflected from the optical distributer and to transfer the focused light to a first output port, and the first and second reflective semiconductor optical amplifiers, the optical distributer, the optical comb filter, the first output port, and the fifth lens constitute a transistor outline can (TOCAN).

In this embodiment, the light generating device further comprises a first lens configured to convert a light incident from the first reflective semiconductor optical amplifier into a parallel light; and a second lens configured to convert a light incident from the second reflective semiconductor optical amplifier into a parallel light.

In this embodiment, the optical comb filter reflects a light not corresponding to pass bands of an incident light along a third direction different from the first and second directions.

In this embodiment, the light generating device further comprises a thermoelectric cooler formed to be adjacent to the first and second reflective semiconductor optical amplifiers, the optical distributer, and the optical comb filter.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a plane view of a light generating device according to an exemplary embodiment of the inventive concept.

FIG. 2 is a lateral view of a light generating device in FIG. 1.

FIGS. 3 and 4 are diagrams for describing a light generating process of a light generating device.

FIG. 5 is a diagram illustrating an output light of a light generating device described with reference to FIGS. 1 to 4.

FIG. 6 is a lateral view of a light generating device according to another exemplary embodiment of the inventive concept.

FIG. 7 is a plane view illustrating an optical generating device according to another exemplary embodiment of the inventive concept.

FIG. 8 is a diagram illustrating a light generating device according to still another exemplary embodiment of the inventive concept.

FIGS. 9 and 10 are diagrams illustrating a light generating process of a light generating device.

### DETAILED DESCRIPTION

The inventive concept is described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or a layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

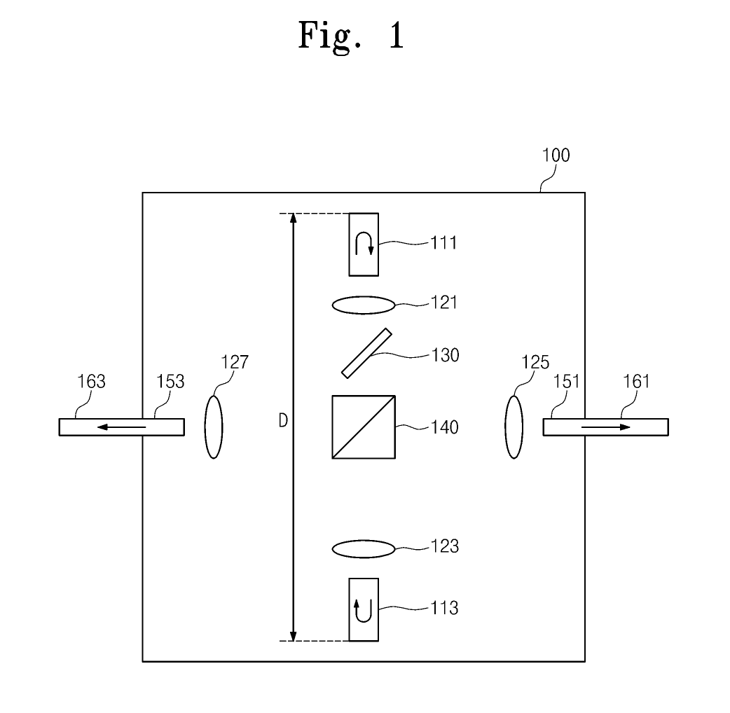

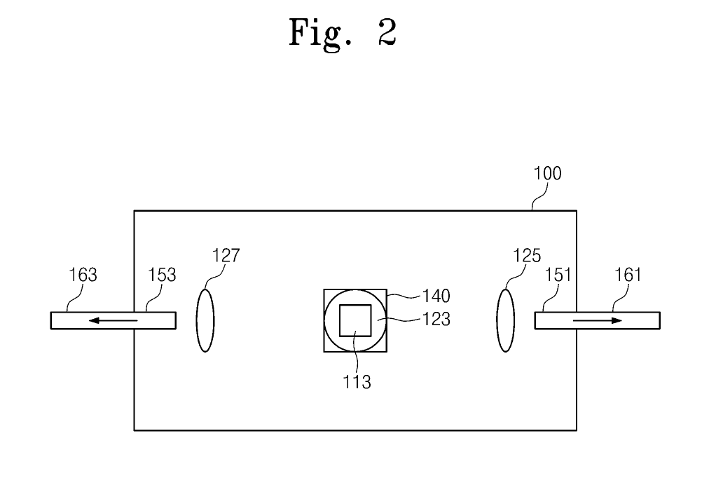

FIG. 1 is a plane view of a light generating device 100 according to an exemplary embodiment of the inventive concept. FIG. 2 is a lateral view of a light generating device 100 in FIG. 1.

Referring to FIGS. 1 and 2, the light generating device 100 may include first and second reflective semiconductor optical amplifiers (RSOA) 111 and 113, first to fourth lenses 121 to 127, an optical comb filter 130, an optical distributer 140, and first and second output ports 151 and 153.

The first RSOA 111, the first lens 121, the optical comb filter 130, the optical distributer 140, the third lens 123, and the second RSOA 113 may be provided along the first direction. The first output port 151, the third lens 125, the optical distributer 140, the fourth lens 127, and the second output port 153 may be provided along the second direction intersecting the first direction.

The first output port 151 may be connected with a wave guiding medium. In an exemplary embodiment, the first output port 151 may be connected with the first optical fiber 161. The second output port 153 may be connected with a wave guiding medium. In an exemplary embodiment, the second output port 153 may be connected with the second optical fiber 163.

The first and second RSOA 111 and 113 may emit a natural light. Further, the first and second RSOA 111 and 113 may amplify an incident light to emit the amplified light. That is, lights emitted from the first and second RSOA 111 and 113 may include the natural light and an amplified reflected light. Below, a light emitted from the first RSOA 111 may be the first light, and a light emitted from the second RSOA 113 may be the second light.

The first RSOA 111 may emit the first light toward the first lens 121. The second RSOA 113 may emit the second light toward the second lens 123. That is, the first and second RSOA 111 and 113 may emit the first and second lights in a face-to-face direction. A distance between the reverse of the first RSOA 111 and the reverse of the second RSOA 113 may be D.

The first to fourth lenses 121 to 127 may be focusing lenses focusing an incident light.

The optical comb filter 130 may have a plurality of pass bands of a comb shape at a frequency domain. Among incident lights upon the optical comb filter 130, lights having frequencies of a comb shape corresponding to pass bands may be passed, and the remaining may be reflected.

The optical distributer 140 may distribute an incident light into at least two portions. In an exemplary embodiment, the optical distributer 140 may pass a part of the incident light and may reflect the remaining thereof. A progressive direction of a light reflected by the optical distributer 140 may be determined according to a progressive direction of the incident light. A part of the incident light upon the optical distributer 140 from the optical comb filter 130 may be penetrated, and the remaining thereof may be reflected to a direction of the fourth lens 127. A part of the incident light to the optical distributer 140 from the second lens 123 may be passed, and the remaining thereof may be reflected to a direction of the third lens 123.

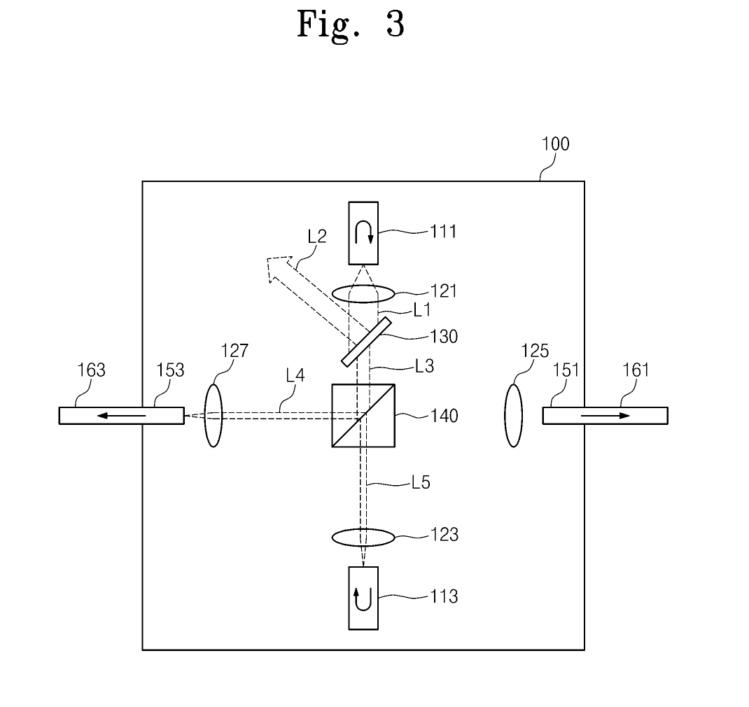

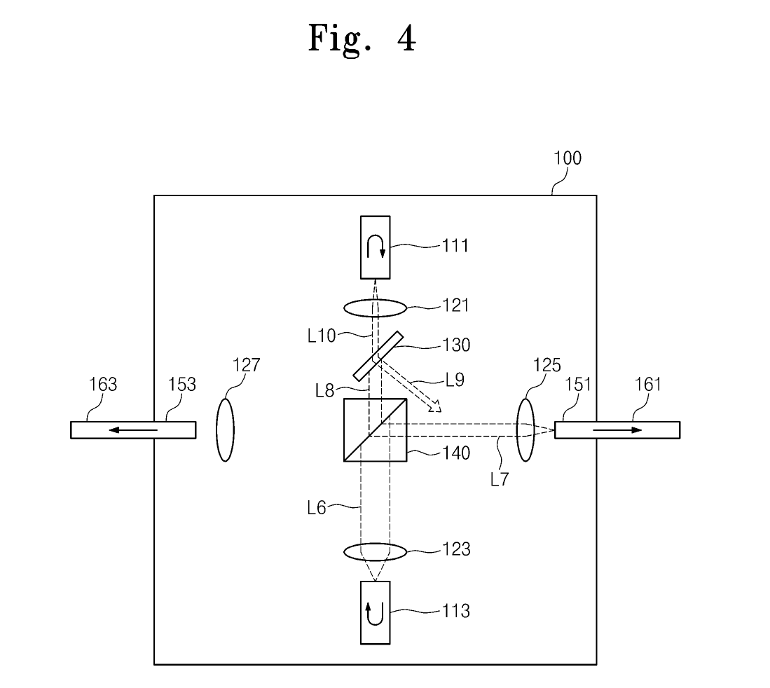

FIGS. 3 and 4 are diagrams for describing a light generating process of the light generating device 100. Referring to FIG. 3, the first RSOA 111 may emit the first light toward the first lens 121. The first lens 121 may focus an incident light so as to be converted into the first parallel light L1. The first parallel light L1 passing the first lens 121 may become incident on an optical comb filter 130.

Among the first parallel light L1 incident upon the optical comb filter 130, a portion corresponding to pass bands of a comb shape may pass the optical comb filter 130. A portion passing the optical comb filter 130 of the first parallel light L1 may be defined as the first filter transmitted light L3. The first filter transmitted light L3 may be incident upon an optical distributer 140 along the first direction. Among the first parallel light L1 incident upon the optical comb filter 130, a portion not corresponding to pass bands of the optical comb filter 130 may be reflected from the optical comb filter 130. A portion reflected from the optical comb filter 130 of the first parallel light L1 may be defined as the first filter reflected light L2. In an exemplary embodiment, the optical comb filter 130 may reflect the first filter reflected light L2 along a direction different from the first and second directions.

The optical distributer 140 may reflect a part of the first filter transmitted light L3 and may pass the remaining thereof. A portion reflected by the optical distributer 140 of the first filter transmitted light L3 may be defined as the first distribution reflected light L4. A portion passed by the optical distributer 140 of the first filter transmitted light L3 may be defined as the first distribution transmitted light L5. In an exemplary embodiment, the optical distributer 140 may reflect the first distribution reflected light L4 to the fourth lens 127 along the second direction. The fourth lens 127 may focus the first distribution reflected light L4 to provide it to the second output port 153, that is, the second optical fiber 163 along the second direction. The optical distributer 140 may pass the first distribution transmitted light L5 to the second lens 123 along the first direction. The second lens 123 may focus the first distribution transmitted light L5 to provide it to the second RSOA 113 along the first direction.

Referring to FIG. 4, the second RSOA 113 may emit the second light to the second lens 123 along a direction opposite to the first direction. The second lens 123 may convert the second light into the second parallel light L6. The second parallel light L6 may be incident upon the optical distributer 140.

The optical distributer 140 may reflect a part of the second parallel light L6 being incident and may pass the remaining thereof. A portion reflected by the optical distributer 140 of the second parallel light L6 may be defined as the second distribution reflected light L7. A portion passed by the optical distributer 140 of the second parallel light L6 may be defined as the second distribution transmitted light L8. In an exemplary embodiment, the optical distributer 140 may reflect the second distribution reflected light L7 to the third lens 125 along a direction opposite to the second direction. The third lens 125 may focus the second distribution reflected light L7 being incident to provide it to the first output port 151, that is, the first optical fiber 161 along a direction opposite to the second direction. The optical distributer 140 may pass the second distribution transmitted light L8 by the optical comb filter 130 along a direction opposite to the first direction. A portion corresponding to pass bands of a comb shape of the optical comb filter 130 among the second distribution transmitted light L8 incident upon the optical comb filter 130 may pass the optical comb filter 130. The portion passing the optical comb filter 130 of the second distribution transmitted light L8 may be defined as the second filter transmitted light L10. The second filter transmitted light L10 may be incident upon the first lens 121 along a direction opposite to the first direction. The first lens 121 may focus the second filter transmitted light L10 to provide it to the first RSOA 111.

Among the second distribution transmitted light L8 incident upon the optical comb filter 130, a portion not corresponding to pass bands of the optical comb filter 130 may be reflected from the optical comb filter 130. A portion reflected from the optical comb filter 130 of the second distribution transmitted light L8 may be defined as the second filter reflected light L9. In an exemplary embodiment, the optical comb filter 130 may reflect the second filter reflected light L9 along a direction different from the first and second directions.

As illustrated in FIGS. 3 and 4, the first distribution transmitted light L5, that is, a part of the first light emitted from the first RSOA 111 may be incident upon the second RSOA 113. The second RSOA 113 may amplify and emit the first distribution transmitted light L5. The second filter transmitted light L10, that is, a part of the second light emitted from the second RSOA 113 may be incident upon the first RSOA 111. The first RSOA 111 may amplify and emit the second filter transmitted light L10 being incident. That is, the first and second RSOA 111 and 113 may constitute a resonator.

A resonator may be formed along the first direction by the first and second RSOA 111 and 113. The optical comb filter 130 may be formed between the first and second RSOA 111 and 113. That is, the second filter transmitted light L10 incident upon the first RSOA 111 may be a light penetrating the optical comb filter 130. The first distribution transmitted light L5 incident upon the second RSOA 113 may be a light passing the optical comb filter 130. Accordingly, a light having a frequency characteristic of a comb shape, that is, a multi-wavelength light of a comb shape may resonate between the first and second RSOA 111 and 113. A resonant frequency may be determined by a distance D between the rear sides of the first and second RSOA 111 and 113.

A part of a light resonated by the first and second RSOA 111 and 113 may be distributed by the optical distributer 140. In an exemplary embodiment, the first distribution reflected light L4 of the first light emitted by the first RSOA 111 may be reflected by the optical distributer 140 so as to be output to the second output port 163. The second distribution reflected light L7 of the second light emitted by the second RSOA 113 may be reflected by the optical distributer 140 so as to be output to the first output port 161. That is, multi-wavelength lights of a comb shape may be output via the first and second ports 161 and 163.

The first filter reflected light L2 of the first light emitted from the first RSOA 111 may be reflected by the optical comb filter 130. The second filter reflected light L9 of the second light emitted from the second RSOA 113 may be reflected by the optical comb filter 130. The first and second reflected lights L2 and L9 may be reflected along a direct different from the first and second directions. Accordingly, the first and second filter reflected lights L2 and L9 don't resonate. That is, the first and second filter reflected lights L2 and L9 may not be output.

In an exemplary embodiment, as illustrated in FIGS. 1 to 4, the first and second filter reflected lights L2 and L9 may be reflected along a direction different from the first and second directions by forming the optical comb filter 130 so as to be inclined in a direction different from the first and second directions.

As described above, a multi-wavelength light of a comb shape may resonate by forming the optical comb filter 130 between two RSOA 111 and 113 which form a resonator. It is possible to reduce the complexity of the light generating device 100 without additional wavelength control. Further, the optical comb filter 130 may be a passive optical device. If the optical comb filter 130 is formed of a medium independent from a temperature, the complexity of the light generating device 100 may be further reduced without additional temperature control.

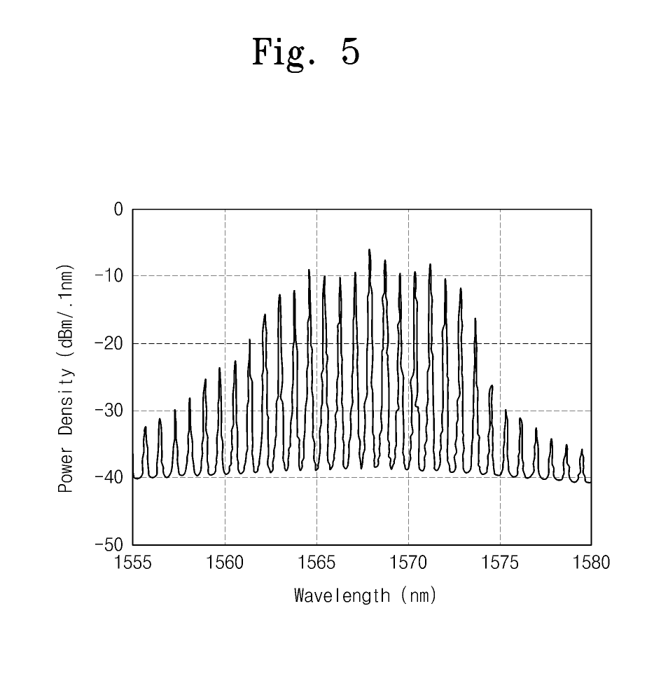

FIG. 5 is a diagram illustrating an output light of a light generating device described with reference to FIGS. 1 to 4. In FIG. 5, a horizontal axis indicates a wavelength (nm), and a vertical axis indicates a power density (dB m/nm).

Referring to FIG. 5, an oscillation wavelength of an output light may coincide with a pass band of an optical comb filter 130. An output over −10 dB and an SMSR (Side-Mode Suppression Ratio) over 30 dB may be obtained from ten channels of a gain centroid wavelength region.

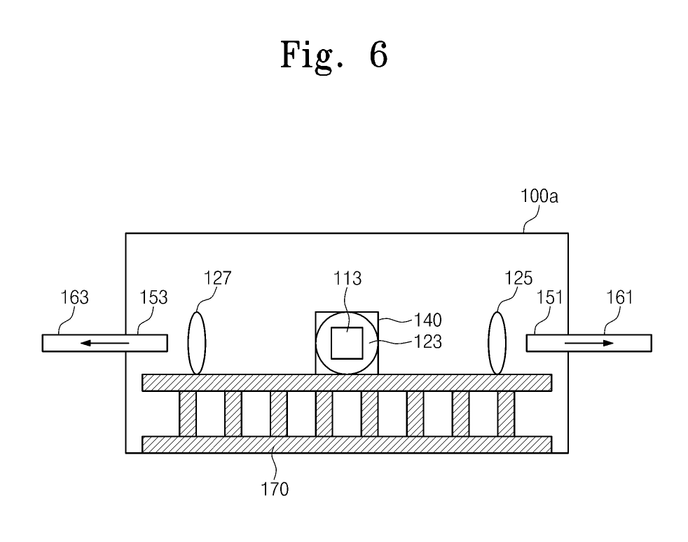

FIG. 6 is a lateral view of a light generating device 100a according to another exemplary embodiment of the inventive concept. As compared with a light generating device 100 in FIG. 2, the light generating device 100a in FIG. 6 may further include a thermoelectric cooler (TEC) 170. The first and second RSOA 111 and 113, the first to fourth lenses 121 to 127, an optical comb filter 130, an optical distributer 140, and the first and second output ports 151 and 153 may be placed on the thermoelectric cooler 170. If the thermoelectric cooler 170 is added, it is possible to prevent that an amplification rate of the first and second RSOA 111 and 113 is reduced.

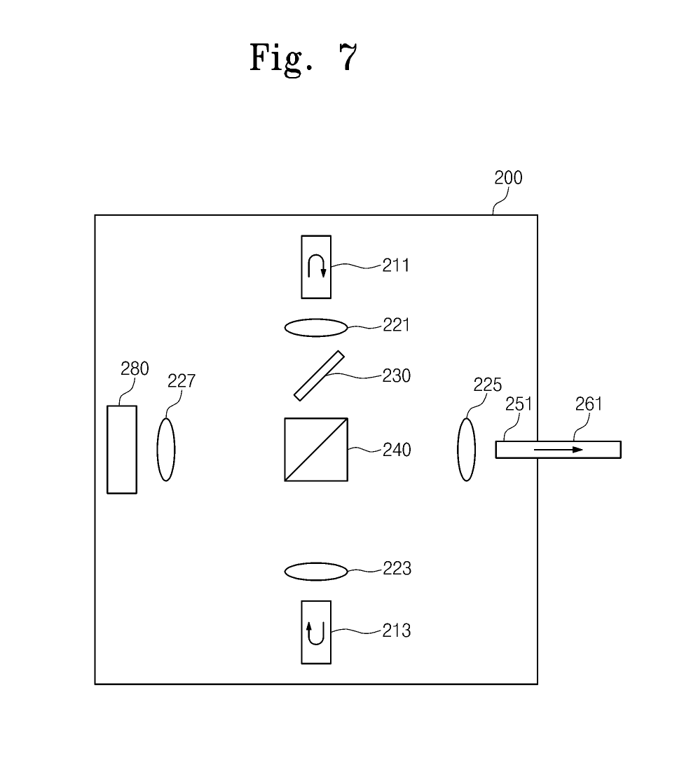

FIG. 7 is a plane view illustrating an optical generating device 200 according to another exemplary embodiment of the inventive concept. Referring to FIG. 7, the light generating device 200 may include the first and second RSOA 211 and 213, the first to fourth lenses 221 to 228, an optical comb filter 230, an optical distributer 240, the first output port 251, and a monitor element 280.

As described with reference to FIGS. 1 to 4, the first RSOA 211, the first lens 221, the optical comb filter 230, the optical distributer 240, the second lens 223, and the second RSOA 213 may be formed along the first direction. The first and second RSOA 211 and 213 may emit lights toward opposite direction each other. The first RSOA 211 may emit the first light along the first direction, and the second RSOA 213 may emit the second light along a direction opposite to the first direction.

The first output port 251, the third lens 225, the optical distributer 240, the fourth lens 228, and the monitor element 280 may be formed along the second direction. The first output port 251 may be coupled with the first optical fiber 261. The optical generating device 200 may be configured the same as that 100 described with reference to FIGS. 1 to 4 except that the monitor element 280 is provided instead of the second output port 153 connected with the second optical fiber 163.

A portion of a multi-wavelength light of a comb shape resonated by the first and second RSOA 211 and 213 may be distributed by the optical distributer 240 so as to be incident upon the monitor element 280. In an exemplary embodiment, as described with reference to FIG. 3, the first distribution reflected light L4 distributed by the optical distributer 140 may be focused by the fourth lens so as to be incident upon the monitor element 280.

The monitor element 280 may monitor an incident light. For example, the monitor element 280 may monitor a power of an incident light. A result monitored by the monitor element 280 may be output to an external device. Outputs of the first and second RSOA 211 and 213 may be adjusted according to the monitoring result. That is, a power of a multi-wavelength light of a comb shape output to the first optical fiber 261 may be adjusted according to the monitoring result. In an exemplary embodiment, the monitor element 280 may include a monitor photo diode (MPD).

In an exemplary embodiment, as described with reference to FIG. 6, a thermoelectric cooler (TEC) can be added to the light generating device 200.

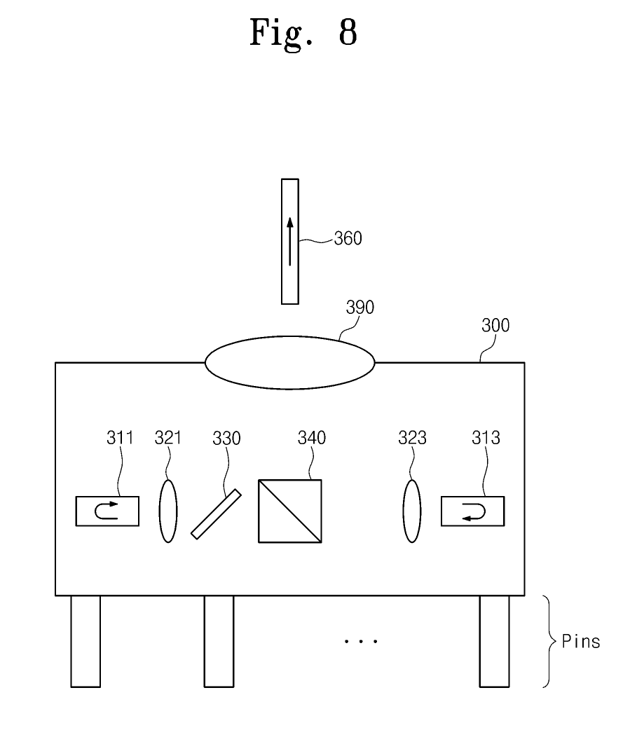

FIG. 8 is a diagram illustrating a light generating device 300 according to still another exemplary embodiment of the inventive concept. Referring to FIG. 8, the light generating device 300 may include the first and second RSOA 311 and 313, the first and second lenses 321 and 323, an optical comb filter 330, an optical distributer 340, and an output port 390. The output port 390 may include a focus lens for focusing an incident light.

The first RSOA 311, the first lens 321, the optical comb filter 330, the optical distributer 340, the second lens 323, and the second RSOA 313 may be formed along the first direction. The first and second RSOA 311 and 313 may emit a light with them being opposite to each other.

The optical distributer 340 and the output port 390 may be formed at an intersection of the first direction and the second direction. A light guiding medium may be formed on the output port 390 along the second direction. In an exemplary embodiment, the optical fiber 360 can be connected.

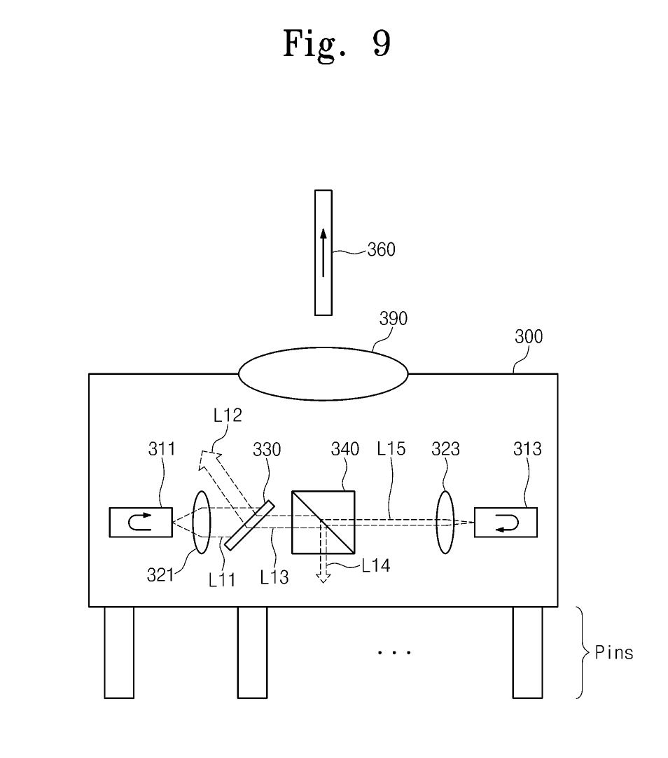

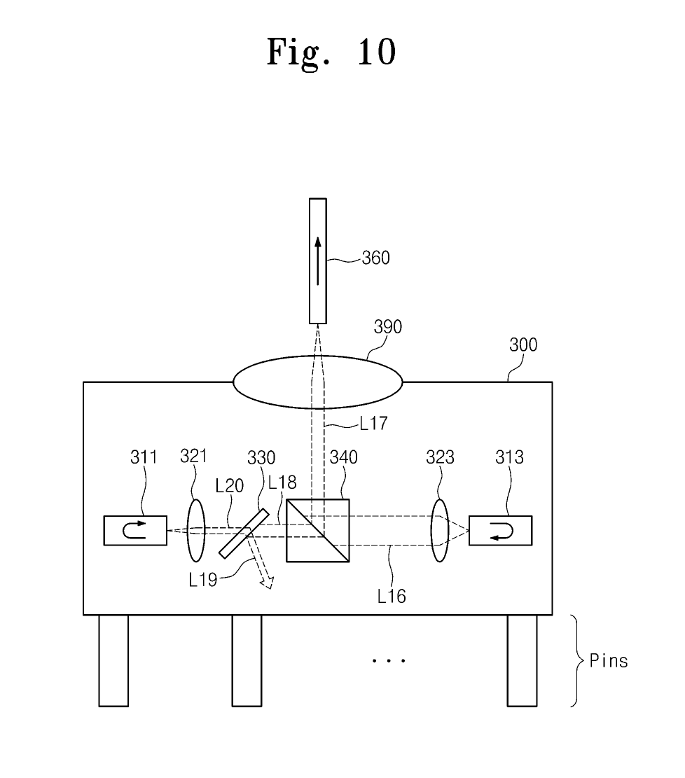

FIGS. 9 and 10 are diagrams illustrating a light generating process of a light generating device. Referring to FIG. 9, the first RSOA 311 may emit the first light to the first lens 321 along the first direction. The first lens 321 may convert the first light into the first parallel light L11. The first parallel light L11 may be incident upon an optical comb filter 330 along the first direction.

A portion not corresponding to pass bands of the optical comb filter 330 of the first parallel light L11 may be reflected from the light comb filter 330. A light reflected from the optical comb filter 330 may be defined as the first filter reflected light L12. The first filter reflected light L12 may be reflected along a direction different from the first and second directions.

A multi-wavelength portion of a comb shape corresponding to pass bands of the optical comb filter 330 of the first parallel light L11 may pass the optical comb filter 330. A light passing the optical comb filter 330 may be defined as the first filter transmitted light L13. The first filter transmitted light L13 may be incident upon the optical distributer 340 along the first direction.

The optical distributer 340 may reflect a part of the first filter transmitted light L13 and may pass the remaining thereof. A portion reflected by the optical distributer 340 of the first filter transmitted light L13 may be defined as the first distribution reflected light L14. The first distribution reflected light L14 may be reflected in an opposite direction of the output port 390 along the second direction intersecting the first direction. That is, the first distribution reflected light L14 may be reflected to a bottom of the light generating device 300.

A portion passing the optical distributer 340 of the first filter transmitted light L13 may be defined as the first distribution transmitted light L15. The first distribution transmitted light L15 may be incident upon the second lens 323 along the first direction.

The second lens 323 may focus the first distribution transmitted light L15 to provide it to the second RSOA 313.

Referring to FIG. 10, the second light emitted from the second RSOA 313 may be incident upon the second lens 323 along a direction opposite to the first direction. The second lens 323 may focus the second light so as to be converted into the second parallel light L16. The second parallel light L16 may be incident upon the optical distributer 340.

The optical distributer 340 may reflect a part of the second parallel light L16 and may pass the remaining thereof. A light reflected by the optical distributer 340 of the second parallel light L16 may be defined as the second distribution reflected light L17. The second distribution reflected light L17 may be incident upon the output port 390 along a direction opposite to the second direction. A focus lens of the output port 390 may focus the second distribution reflected light L17 so as to be incident upon the optical fiber 360.

A portion passing the optical distributer 340 of the second parallel light L16 may be defined as the second distribution transmitted light L18. The second distribution transmitted light L18 may be incident upon the optical comb filter 330 along a direction opposite to the first direction.

A portion not corresponding to pass bands of the optical comb filter 330 of the second distribution transmitted light L18 may be reflected from the optical comb filter 330. A light reflected from the optical comb filter 330 may be defined as the second filter reflected light L19. The second filter reflected light L19 may be reflected along a direction different from the first and second directions.

A multi-wavelength portion of a comb shape corresponding to pass bands of the optical comb filter 330 of the second distribution transmitted light L18 may pass the optical comb filter 330. A light passing the optical comb filter 330 may be defined as the second filter transmitted light L20. The second filter transmitted light L20 may be incident upon the first lens 321 along a direction opposite to the first direction.

The first lens 321 may focus the second filter transmitted light L20 so as to be incident upon the first RSOA 311.

Referring to FIGS. 8 to 10, the first and second RSOA 311 and 313 may form a resonator along the first direction. The optical comb filter 330 may be formed within the resonator. Accordingly, a multi-wavelength light of a comb shape may resonate at the resonator formed by the first and second RSOA 311 and 313.

A portion of the multi-wavelength light of a comb shape resonated by the first and second RSOA 311 and 313 may be output to the output port 390 by the optical distributer 340. That is, a multi-wavelength light of a comb shape may be output to the optical fiber 360 via the output port 390.

The light generating device 300 may be made by a transistor outline can (TOCAN). In this case, as illustrated in FIGS. 8 to 10, a plurality of pins may be formed at a lower part of the light generating device 300.

In an exemplary embodiment, as described with reference to FIG. 6, a thermoelectric cooler (TEC) can be added to the light generating device 300.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A light generating device comprising:
a first reflective semiconductor optical amplifier configured to emit a first light along a first direction;
a second reflective semiconductor optical amplifier being opposite to the first reflective semiconductor optical amplifier and configured to emit the second light in a direction opposite to the first direction;
an optical distributer formed between the first and second reflective semiconductor optical amplifiers and configured to reflect a part of an incident light and to pass the remaining of the incident light; and
an optical comb filter formed between the optical distributer and the first reflective semiconductor optical amplifier and configured to pass a wavelength component of a specific period.

2. The light generating device of claim 1, wherein the optical distributer reflects a part of the second light and passes the remaining of the second light toward the optical comb filter.

3. The light generating device of claim 2, wherein the optical distributer reflects a part of the first light in a direction opposite to the second direction and passes the remaining of the second light toward the second reflective semiconductor optical amplifier.

4. The light generating device of claim 3, further comprising:
a third lens configured to focus a light reflected along the second direction from the optical distributer and to transfer the focused light to a first output port; and
a fourth lens configured to focus a light reflected along a direction opposite to the second direction from the optical distributer and to transfer the focused light to a second output port.

5. The light generating device of claim 3, further comprising:
a monitor photo diode configured to monitor a light reflected along a direction opposite to the second direction from the optical distributer.

6. The light generating device of claim 2, further comprising:
a fifth lens configured to focus a light reflected from the optical distributer and to transfer the focused light to a first output port, and
wherein the first and second reflective semiconductor optical amplifiers, the optical distributer, the optical comb filter, the first output port, and the fifth lens constitute a transistor outline can (TOCAN).

7. The light generating device of claim 1, further comprising:
a first lens configured to convert a light incident from the first reflective semiconductor optical amplifier into a parallel light; and
a second lens configured to convert a light incident from the second reflective semiconductor optical amplifier into a parallel light.

8. The light generating device of claim 2, wherein the optical comb filter reflects a light not corresponding to pass bands of an incident light along a third direction different from the first and second directions.

9. The light generating device of claim 1, further comprising:
a thermoelectric cooler formed to be adjacent to the first and second reflective semiconductor optical amplifiers, the optical distributer, and the optical comb filter.
